(19) United States
(12) Patent Application Publication
(10) Pub. No.: US 2013/0009167 A1
(43) Pub. Date: Jan. 10, 2013

(54) LIGHT EMITTING DIODE WITH PATTERNED STRUCTURES AND METHOD OF MAKING THE SAME

(75) Inventors: Wei-Sin TAN, Oxford (GB); Alistair Paul CURD, High Wycombe (GB); Valerie BERRYMAN-BOUSQUET, Chipping Norton (GB)

(73) Assignee: SHARP KABUSHIKI KAISHA, Osaka (JP)

(21) Appl. No.: 13/176,872

(22) Filed: Jul. 6, 2011

(51) Int. Cl. H01L 33/02; H01L 33/58; H01L 33/62

(52) U.S. Cl. 257/77; 257/99; 257/76; 438/46; 257/98; 438/29; 257/E33.066; 257/E33.023; 257/E33.013; 257/E33.06

(57) ABSTRACT

A light emitting diode is provided which includes an active region in combination with a current spreading layer; and a crystalline epitaxial film light extraction layer in contact with the current spreading layer, the light extraction layer being patterned with nano/micro structures which increase extraction of light emitted from the active region.

### TECHNICAL FIELD

The present invention relates to a light emitting diode (LED) device and a method of making the same, and in particular an LED device structure with a patterned crystalline light extraction layer obtained from epitaxial growth in contact with the current spreading layer.

### BACKGROUND ART

There is growing popularity in the use of light emitting diodes (LED) for general lighting and backlight applications to replace conventional light sources such as incandescent bulbs, halogen bulbs, cold cathode fluorescent lamps (CCFL) and compact fluorescent lamps due to the lower power consumption and the use of non-toxic materials in LEDs. To produce white LEDs, indium-gallium nitride-based blue LED chips emitting at ˜450 nm is typically used to excite a phosphor layer to create white light. However, due to the large refractive index contrast between GaN (n˜2.5) and air, the majority of generated light has difficulty escaping the structure and is waveguided within the semiconductor layer itself, subsequently resulting in absorption. The poor light extraction efficiency (LEE) in these structures severely limits the device performance. In a blue LED chip without any special light extraction features, the LEE of the chip is only ˜25-30%. A variety of methods have been employed to increase LEE, such as surface roughening, photonic crystal, flip-chip mounting, chip-shaping, and patterned sapphire substrates. Among these, patterned sapphire substrates (PSS) [Yamada et. al, Japanese Journal of Applied Physics, vol. 41, L1431-1433, (2002)] are commonly used in commercial blue LED chips to increase LEE to ˜60%.

Besides PSS structures, a variety of methods have been employed to improve LEE further. The key feature towards increasing LEE is to reduce total internal reflection (TIR) of light at the GaN(ITO)-air interface, and by doing so light will be extracted out of the structure quicker and reduce the probability of being absorbed in the structure. Surface patterning with periodic nano/micro structures have been reported in the literature as means to reduce TIR in these structures. LED chips in commercial products are typically small area devices (i.e. 300 μm×800 μm). More than 50% of light is extracted by edge emission through the facets of a singulated chip, and the remainder is extracted through the top surface, when a reflector is placed at the bottom of the chip. If the chip size is increased, surface emission becomes dominant over edge emission. However, light extraction from the surface is challenging due to TIR at the GaN-air interface, resulting in increased absorption for large area chips compared to smaller ones. In order to not compromise chip efficiency, manufacturers are using an array of small area LED chips instead of a single large chip to form a high power LED module.

In U.S. Pat. No. 5,955,749 (published date 21 Sep. 1999), Joannopolous et al describes the use of photonic crystal structures by etching periodic nanopatterns into the p-GaN layer to improve light extraction from the surface. However, this method will also result in increased operating voltage, as reported by Chhajed et. al [Applied Physics Letters, vol. 98, 071102 (2011)]. Kim et. al [Applied Physics Letters, vol. 91, 171114 (2007)] employed surface nano-scale patterning on the indium tin oxide (ITO) current spreading layer to increase light extraction. Although an increase in LEE is observed, patterning the ITO layer reduces the effective ITO thickness and subsequently increases the sheet resistance.

From the examples above, it is evident that using surface patterning structures that does not involve etching into the p-GaN or ITO layer is preferable, since any improvement in LEE will be offset by an increase in operating voltage due to higher series resistance. An alternative method is to deposit a patterned high refractive index layer over the ITO film. Since the refractive index of ITO is ˜1.9-2.0 (450 nm), the high index film will need to have a higher refractive index than the ITO layer. Light emitted will then be coupled into the high index layer, which is patterned with micro/nano structures to extract light out. Light extraction will not be effective if the high index layer is not patterned. Using the same concept, Cho et. al [Japanese Journal of Applied Physics, vol. 49, 102103 (2010)] reported the use of nanopatterned TiO₂ (n˜2.2) on top of the ITO layer to increase LEE. The author reported a 12% increase in light output power, and since the p-GaN and ITO layer is not etched, the current-voltage (I-V) characteristics is unaffected. This approach also improves light extraction through surface emission, therefore giving manufacturers the option of using large area LED chips over an array of small ones without compromising efficiency.

The high index layer approach will be more effective the higher its refractive index, and is ideally the same refractive index as the GaN layer (n˜2.5). However, it is not easy to achieve transparent films with refractive indices larger than 2.2. Conventional films such as ZnO, ZrO₂, TiO₂, Ta₂O₅, ITO, SiOₓN_{y}, SiNₓ, AlN, ZnS, and IZO have refractive indices of ˜2.0-2.2 at 450 nm. Attempts to increase the refractive index of these films are not trivial, since the optical transparency of the film will need to remain very high quality in an LED device. Since emitted light is reflected/refracted many times in an LED structure before escaping into air, a slight increase in absorption of the high index film can result in a sharp decrease in output power.

An embodiment of a conventional LED structure is described in U.S. Pat. No. 6,657,236 (B. Thibeault et. al, issued 2 Dec. 2003). An array of LEE features is formed on the current spreading layer to improve LEE. The LEE features are formed by evaporation, chemical vapour deposition (CVD) or sputtering. It is preferable to use GaN as the LEE features in this case, but high quality crystalline GaN films cannot be achieved using the methods described in the prior art. Crystalline GaN films can also be achieved using epitaxial growth methods, such as metal organic chemical vapour deposition (MOCVD) or molecular beam epitaxy (MBE). Furthermore, crystalline quality GaN film cannot be achieved by growing directly on the current spreading layer (i.e. ITO), since attempts to grow GaN directly on ITO or any other metallic/oxide films will result in poor quality amorphous films. FIG. 1 [Optical Review, vol. 15, no. 5, pp. 251, 2008] shows comparison of the refractive index (n) and absorption coefficient (α) of a crystalline GaN (c-GaN) and amorphous GaN film of two different thicknesses (140 nm and 400 nm). From the graph, amorphous GaN films have a lower refractive index and higher absorption than crystalline GaN at 450 nm, and thus are not suitable for use as a light extraction layer. Therefore, only the use of crystalline quality GaN film is possible and such films can also be achieved using epitaxial growth.

In U.S. Pat. No. 7,244,957 (N. Nakajo et. al, issued 17 Jul. 2007), a patterned niobium doped TiO₂ layer is used as the light extraction layer. Niobium doping is used to improve the electrical conductivity of the film, enabling the TiO₂ layer to act both as a LEE layer and also a current spreading layer. This LEE improvement is limited for this structure since it is difficult to achieve refractive index higher than 2.2 for TiO₂.

US 2008/0121918 (S. P. DenBaars et. al, published 29 May 2008) describes an LED structure which is mounted p-side down and the N-polarity face of n-type GaN is wet etched with KOH to form conical light extraction features. The use of p-side down mounting is more complicated than conventional p-side up mounting and this structure requires the use of bulk GaN substrates, which is more expensive than conventional GaN on sapphire substrate structures.

FIG. 2 is an LED structure in US 2010/0187555 (A. Murai et. al, published date 29 Jul. 2010). A bulk ZnO substrate is wafer bonded onto a GaN LED structure, and then patterned to increase light extraction. The thick bulk ZnO layer benefits from increased thermal and electrical conductivity. However, the effectiveness of this structure is limited due to the low refractive index (n˜2.2) of ZnO.

From these examples, there is a need in the art for LED devices with good light extraction efficiency. An object of the present invention is to provide an LED with good light extraction through the use of high refractive index light extraction layer, and this will be key towards realisation of high efficiency nitride LEDs.

### SUMMARY OF INVENTION

The present invention provides an LED structure with good light extraction properties. The invention includes a crystalline quality epitaxial GaN film light extraction layer grown on a separate substrate, which is mechanically bonded onto the current spreading layer of a GaN LED structure. Light extraction through surface emission will also be improved for this structure, which enables large area LED chips to be made without compromising efficiency.

According to an aspect of the invention, a light emitting diode is provided which includes an active region in combination with a current spreading layer; and a crystalline epitaxial film light extraction layer in contact with the current spreading layer, the light extraction layer being patterned with nano/micro structures which increase extraction of light emitted from the active region.

According to another aspect, the active region in combination with the current spreading layer includes a conductive n-type region on a substrate, the active region on the n-type region, a p-type region on the active region, and the current spreading layer on the p-region region.

In accordance with another aspect, the crystalline epitaxial film light extraction layer is bonded directly onto the current spreading layer.

According to still another aspect, the crystalline epitaxial light extraction layer is bonded onto the current spreading layer with an intermediate adhesive layer.

In yet another aspect, the intermediate adhesive layer is optically transparent and has a similar or higher refractive index than a refractive index of the current spreading layer.

According to another aspect, the crystalline epitaxial film light extraction layer has a doping level equal to or greater than 10¹⁸ cm⁻³.

According to still another aspect, a shape of the nano/micro structures is at least one of a square, circle, triangle or combination thereof.

In accordance with another aspect, the nano/micro structures have a height of between 10 nm and 10 μm, and a diameter of between 100 nm and 10 μm.

According to still another aspect, the current spreading layer is made of indium tin oxide, indium zinc oxide, zinc oxide or indium zinc tin oxide.

In accordance with yet another aspect, the crystalline epitaxial film light extraction layer is any one or more of GaN, AlGaN, InGaN, AlInGaN, or diamond.

In yet another aspect of the invention, a method of making a light emitting diode is provided. The method includes forming an active region in combination with a current spreading layer; and providing a crystalline epitaxial film light extraction layer in contact with the current spreading layer, the light extraction layer being patterned to form nano/micro structures which increase extraction of light emitted from the active region.

According to another aspect, the method includes forming the active region in combination with the current spreading layer on a first substrate; expitaxially growing the crystalline epitaxial film light extraction layer on a second substrate that is separate from the first substrate; and mechanically bonding the crystalline epitaxial film light extraction layer on the second substrate to the current spreading layer on the first substrate.

According to yet another aspect, the method includes forming a conductive n-type region on a first substrate, forming the active region on the n-type region, forming a p-type region on the active region, and forming the current spreading layer on the p-type region; epitaxially growing the crystalline epitaxial film light extraction layer on a second substrate that is separate from the first substrate; mechanically bonding the crystalline film light extraction layer on the second substrate to the p-type region on the first substrate; following the mechanical bonding, removing the second substrate; and forming the nano/micro structures on a surface of the crystalline film light extraction layer exposed by the removal of the second substrate.

In accordance with another aspect, the crystalline epitaxial film light extraction layer is mechanically bonded directly onto the current spreading layer.

According to another aspect, the crystalline epitaxial light extraction layer is mechanically bonded onto the current spreading layer using an intermediate adhesive layer.

According to yet another aspect, the intermediate adhesive layer is optically transparent and has a similar or higher refractive index than a refractive index of the current spreading layer.

In accordance with still another aspect, the second substrate is one of a sapphire, silicon or silicon carbide substrate.

According to another aspect, a shape of the nano/micro structures is at least one of a square, circle, triangle or combination thereof.

In still another aspect, the nano/micro structures have a height of between 10 nm and 10 μm.

According to yet another aspect, the nano/micro structures have a diameter of between 100 nm and 10 μm.

According to another aspect, the current spreading layer is made of indium tin oxide, indium zinc oxide, zinc oxide or indium zinc tin oxide.

In accordance with another aspect, the crystalline epitaxial film light extraction layer is any one or more of GaN, AlGaN, InGaN, AlInGaN, or diamond.

According to another aspect, the crystalline epitaxial film light extraction layer has a doping level equal to or greater than 10¹⁸ cm⁻³.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

In the annexed drawings, like references indicate like parts or features:

FIG. 1 is the refractive index and absorption of crystalline and amorphous GaN layer as reported in the literature;

FIG. 2 is another known LED structure with light extraction features;

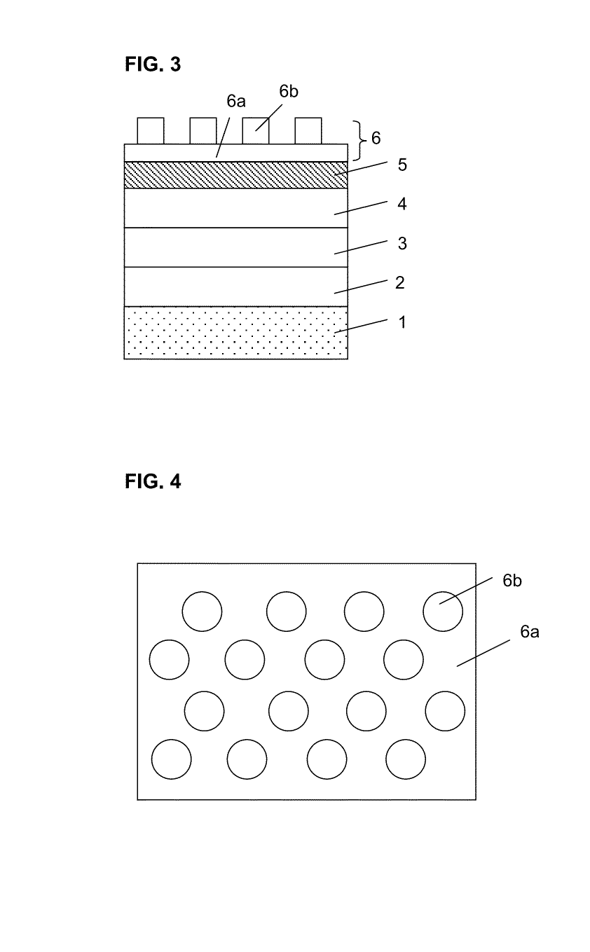

FIG. 3 is a general schematic diagram of an LED device structure in accordance to the invention;

FIG. 4 is schematic top view of nano/micro structures formed on the LED in FIG. 5,

FIGS. 5A and 5B are simulated results showing the effect of increasing refractive indices with light extraction efficiency;

FIG. 6 is a schematic diagram of an LED device structure according to Embodiment 2 of the invention;

FIG. 7 is a schematic diagram of an LED device structure according to Embodiment 3 of the invention;

FIGS. 8A through 8G are schematic diagrams of an example of the LED device structure construction according to Embodiment 4 of the invention;

### DESCRIPTION OF REFERENCE NUMERALS

1 substrate
2 conductive n-type region
3 active region
4 conductive p-type region
5 p-electrode current spreading layer
6 crystalline film light extraction layer
6a un-patterned base layer
6b nano/micro structures
8 optically transparent intermediate adhesive layer
9 transparent conducting layer
10 highly doped crystalline film light extraction layer
10a highly doped base-layer
10b highly doped nano/micro structures
11 substrate
12 conductive n-type region
13 active region
14 conductive p-type region
15 p-electrode current spreading layer
16 sacrificial substrate
17 epitaxially grown crystalline film light extraction layer
17a un-patterned base layer
17b nano/micro structures
18, 18a optically transparent intermediate adhesive layer

### DETAILED DESCRIPTION OF INVENTION

The present invention provides an LED device with good optical light extraction efficiency. The LED structure includes a periodic nano/micro structure on a crystalline quality epitaxial film, formed on top of the current spreading layer. The crystalline film preferably has a higher refractive index than the current spreading layer, in order to enhance light extraction efficiency. Surface emission of light will also be enhanced, which enables large area LED chips to be used instead of an array of small LED chips without affecting chip efficiency. The invention will be detailed through the description of embodiments, wherein like reference numerals are used to refer to like elements throughout.

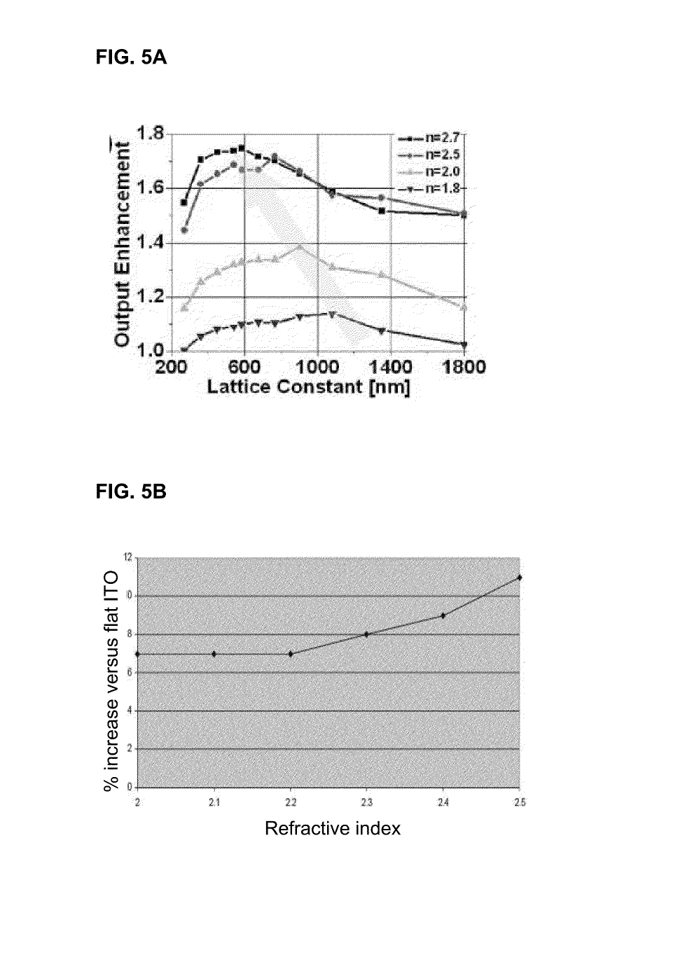

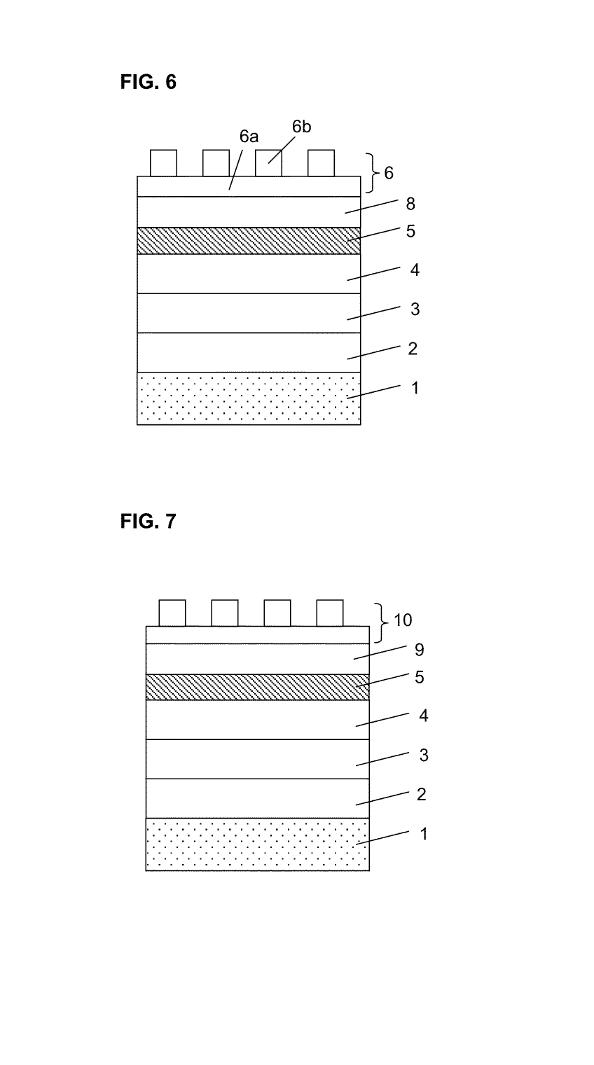

According to the invention, an LED with good light extraction efficiency may be obtained. As illustrated in FIG. 3, the LED structure includes a substrate 1, a conductive n-type region 2, an active region 3, a conductive p-type region 4, a p-electrode current spreading layer 5 and an epitaxially grown crystalline film light extraction layer 6 formed on top of the current spreading layer. The crystalline epitaxial film light extraction layer 6 includes an un-patterned base layer 6a, and a patterned portion that is patterned with nano/micro structures 6b as means to improve light extraction efficiency. The feature sizes of the patterned structures 6b are preferably between 100 nm and 10 μm in diameter, and 10 nm and 10 μm in height, respectively. The nano/micro structures 6b can take any particular shape and arrangement, such as squares, circles, triangles etc., or any combination of these shaped structures and are preferably arranged in any of various types of periodic arrays, but may also be randomly arranged. FIG. 4 illustrates the top view of the LED structure of FIG. 3 which utilizes circular shaped nano/micro structures 6b. The un-patterned base layer 6a of the crystalline film may have a thickness of between 0 nm and 10 μm.

### Embodiment 1

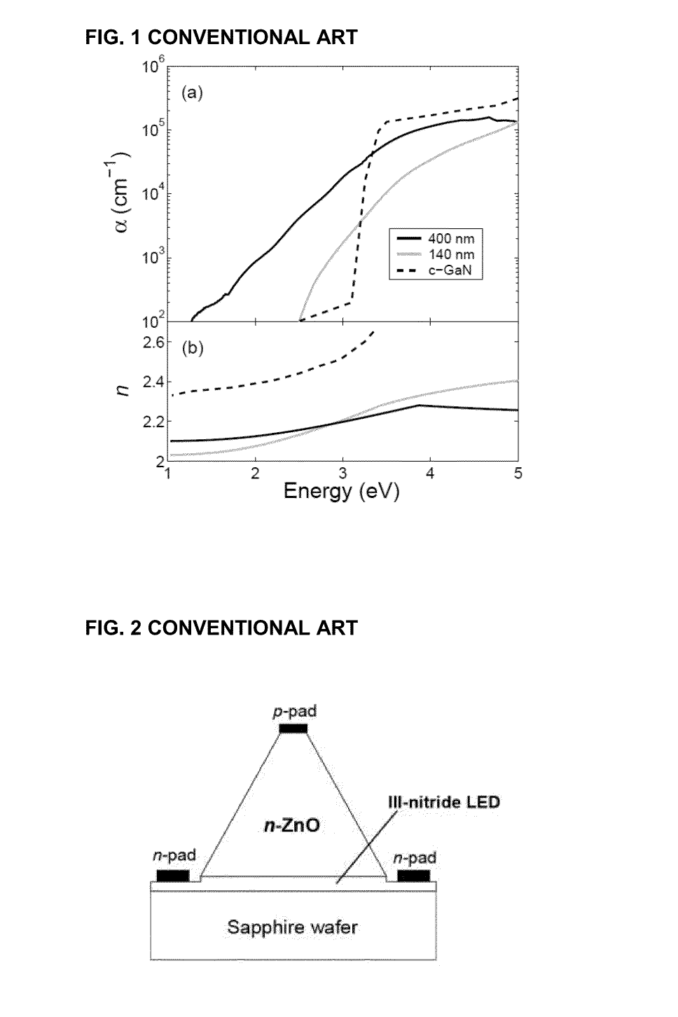

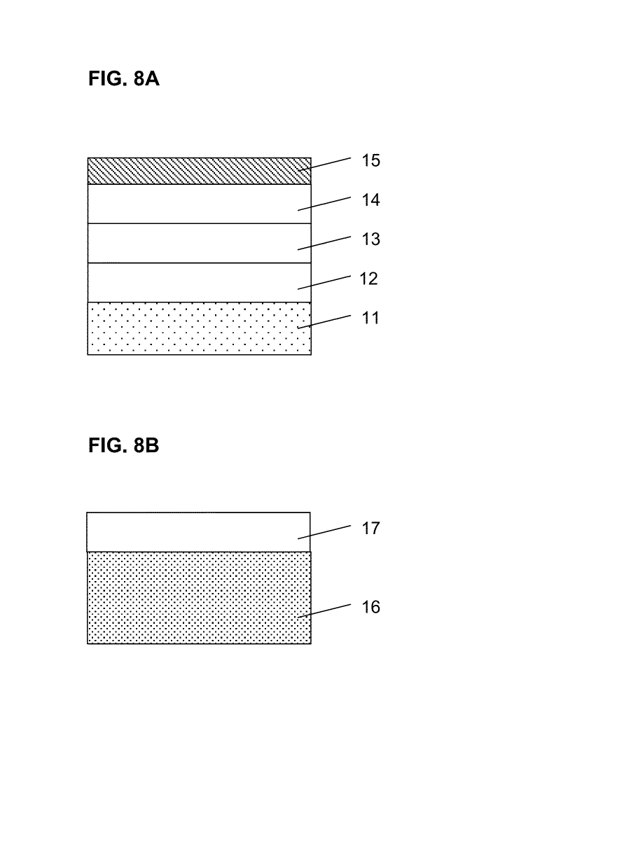

Referring again to FIG. 3, a first particular embodiment of an LED device in accordance with the present invention is illustrated. The LED device includes a crystalline epitaxially grown light extraction layer 6 formed on top of the current spreading layer 5. The current spreading layer 5 is preferably a transparent conducting oxide film, such as indium tin oxide (ITO), indium zinc oxide (IZO) or indium zinc tin oxide (IZTO), but can also be made of one or more metallic layers such as Ni, Ti, Au, Ag, Pt, Hf, Pd, or Al. To enable effective light extraction efficiency, the crystalline film light extraction layer 6 will preferably have a similar (e.g., ±0.1) or higher refractive index than the current spreading layer 5, and ideally similar to that of GaN. Examples of epitaxially grown materials that can be used as the crystalline film light extraction layer 6 are any one or more of GaN, InGaN, AlGaN, AlInGaN or diamond. This layer 6 is grown epitaxially using conventional epitaxial growth techniques, and therefore further details of the epitaxial growth have been omitted for sake of brevity. The layer 6 is of crystalline quality, since amorphous quality films will introduce absorption and have lower refractive index than crystalline ones, as depicted in FIG. 1. FIG. 5A [Applied Physics Letters, vol. 92, 2411118 (2008)] illustrates a simulated result of the gradual improvement in LEE as the refractive index of the light extraction layer is increased for GaN-based LEDs. FIG. 5B, shows the simulated structure in FIG. 4 as a function of increasing refractive indices for the crystalline film light extraction layer 6, and LEE is shown to increase with higher index films.

### Embodiment 2

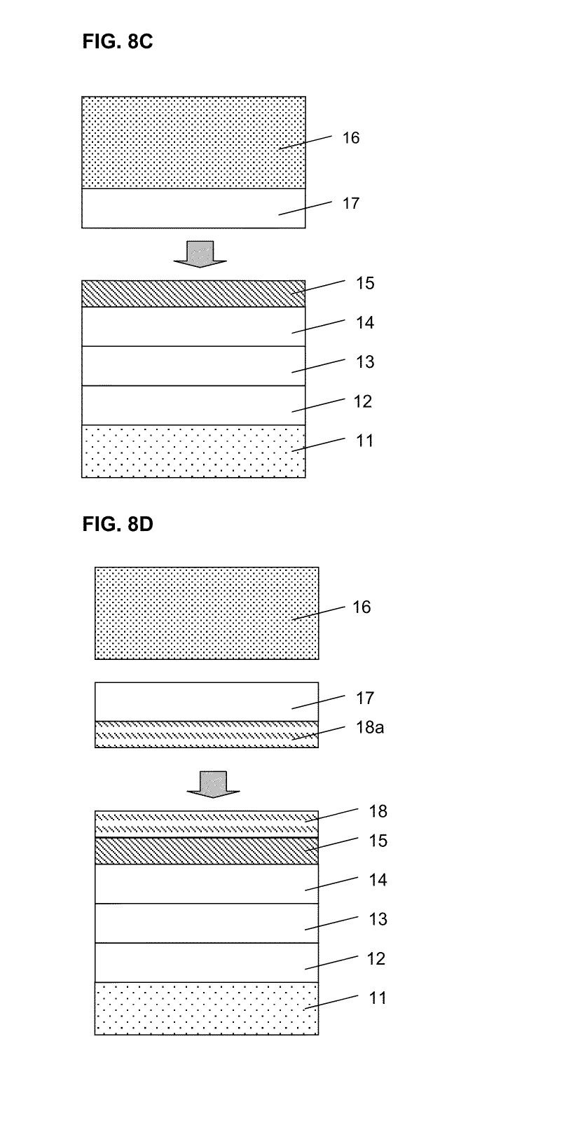

According to this embodiment, the general structure in FIG. 4 can be modified to the structure shown in FIG. 6. For this structure, an optically transparent intermediate layer 8 is sandwiched between the current spreading layer 5 and the patterned crystalline film light extraction layer 6, and acts as the adhesive layer between the two layers. The adhesive layer 8 can be made of one or more layers such as SiO₂, Al₂O₃, SiNₓ, SiONₓ, ITO, IZO, ITZO, Ta₂O₅, TiO₂, ZnO, ZnS, AlN, polyimide, SU8 or benzocyclobuten (BCB) and this layer 8 should preferably have a higher refractive index than the current spreading layer 5, in order to effectively couple light into the crystalline film light extraction layer 6.

### Embodiment 3

As broadly described herein, the crystalline film light extraction layer in the present invention can be doped or undoped. For example, the crystalline film light extraction layer may be intrinsically undoped or include only unintentional background doping. Alternatively, the crystalline film light extraction layer may be intentionally doped in order to alter properties of the layer.

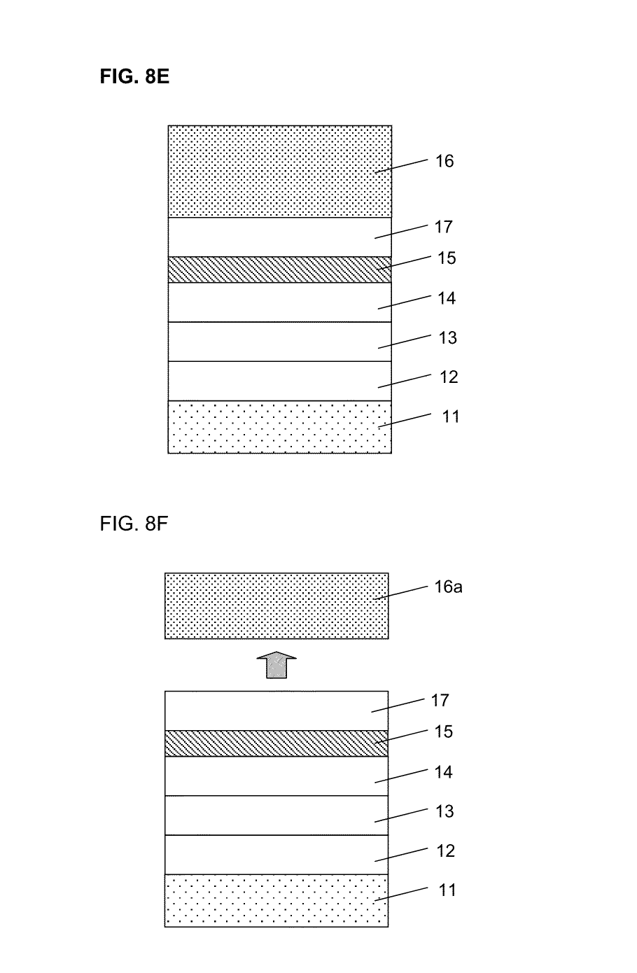

In the case of Embodiment 3 of the invention, the structures in FIG. 3 and FIG. 6 can be modified to the structure shown in FIG. 7. In this structure, the adhesive layer between a crystalline film light extraction layer 10 and current spreading layer 5 is a transparent conducting layer 9, and may have a layer thickness between 0 nm to 10 μm. The crystalline film light extraction layer 10 is a highly doped crystalline material in this embodiment, e.g., n-type GaN. Using a highly doped material (with doping levels≧10¹⁸ cm⁻³) as the un-patterned base layer 10a and patterned nano/micro structures 10b will help improve current spreading properties on the resistive p-GaN film current spreading layer 5, resulting in improved electrical properties of the LED device, in addition to higher light extraction efficiency. In an alternative embodiment, doping of the crystalline film light extraction layer 10 may instead be on the order of 10¹⁵ to 10¹⁷ cm⁻³, for example.

### Embodiment 4

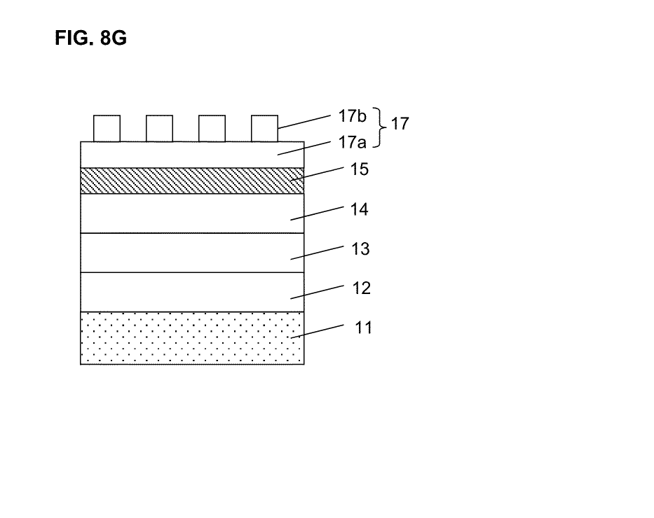

According to this embodiment, the method of making the structure described in Embodiments 1-3 is described. FIG. 8A is a basic LED device structure which begins with an active region in combination with a current spreading layer, for example with a (first) substrate 11, a conductive n-type region 12, an active region 13, a conductive p-type region 14 and a p-electrode current spreading layer 15, such as ITO, formed on the p-type region 14. FIG. 8B represents an epitaxially grown crystalline (Al,In)GaN film light extraction layer 17 grown on a sacrificial (second) substrate 16. For this example, we will assume that a silicon substrate is used as the sacrificial substrate 16 material, but can also be made of other material such as silicon carbide, sapphire or GaN. The wafers represented in FIGS. 8A and 8B may be formed using well-known techniques, and therefore further details of their formation have been omitted herein for sake of brevity. The wafers of FIGS. 8A and 8B are then brought into contact and bonded with each other. For example, FIG. 8C shows a direct wafer bonding approach, whereby the wafers in FIGS. 8A and 8B are mechanically bonded/fused directly together, the epitaxially grown crystalline film light extraction layer 17 in direct contact with the current spreading layer 15, without using any intermediate layers. The mechanical bonding process is typically performed at elevated temperatures and applied pressure between room temperature and up to 600° C. The mechanics and setup for wafer bonding is already well established and will not be repeated here [See, e.g., V. Dragoi et. al, “Adhesive wafer bonding for MEMs applications,” Proceedings of SPIE, vol. 5516, pp. 160 (2003)]. As referred to herein, mechanical bonding of the crystalline film light extraction layer to the current spreading layer includes both bonding (e.g., with adhesive) and fusing of the respective layer.

FIG. 8D illustrates an alternative approach using adhesive bonding, whereby an optically transparent intermediate adhesive layer 18 is used to bond the two wafers together. While spin-on-glass and benzocyclobuten are most commonly used for adhesive bonding, these layers typically have lower refractive indices (n<2.0) than the ITO current spreading layer 15. For efficient light extraction purpose, using higher index adhesive materials such as SiN [see, e.g., R. Bower et. al, Applied Physics Letters, vol. 62, no. 26, pp. 3485-3487 (1993)] or ITO for the intermediate adhesive layer 18 are preferred. The adhesive layer 18 can be applied on either one or both wafers (e.g., 18a on the light extraction layer 17) for the wafer bonding process.

FIG. 8E illustrates the schematic diagram of both wafers after a direct wafer bonding process as described above with respect to FIG. 8C (the adhesive bonding approach of FIG. 8D is not shown). The Si sacrificial substrate 16 can then be removed either using dry or wet etching methods as represented in FIG. 8F. For crystalline GaN film light extraction layers grown on Si substrates, wet chemical etching of the Si substrate 16 is a selective process with respect to the light extraction layer 17, thus an etch stop process is automatically achieved once the substrate 16 is etched off. For crystalline GaN film light extraction layers grown on sapphire or SiC substrates, the sacrificial substrate 16 can be removed from the light extraction layer 17 using laser lift-off (LLO) process. Once the crystalline epitaxially grown (Al,In)GaN film light extraction layer 17 is transferred onto the current spreading layer 15 of the LED device structure, nano/micro structures 17b are patterned on the exposed surface of the layer 17, as shown in FIG. 8G. The un-patterned base layer 17a can have a thickness of 0 nm to 10 μm.

The nano or micro structures can be formed using conventional methods such as optical contact lithography, electron-beam lithography, stepper lithography, nanoimprint lithography, deep UV lithography and other known methods.

The present invention provides an LED structure with good light extraction properties. The invention includes a crystalline quality epitaxial GaN film light extraction layer grown on a separate substrate, which is mechanically bonded onto the current spreading layer of a GaN LED structure. Light extraction through surface emission will also be improved for this structure, which enables large area LED chips to be made without compromising efficiency.

The invention provides for the light extraction layer to be optically transparent, of crystalline quality and obtained from epitaxial growth. The light extraction layer will preferably have a higher refractive index than the current spreading layer and preferably similar or higher than that of the GaN film. The light extraction layer is patterned with micro/nano structures to act as light extraction features.

The crystalline film light extraction layer is a highly doped material, which improves the current spreading properties of the LED device, in addition to its enhanced light extraction features.

The light extraction layer is mechanically bonded directly onto the current spreading layer using direct wafer bonding, i.e., without an intermediate layer.

The light extraction layer may be mechanically bonded onto the current spreading layer using an optically transparent intermediate layer, and this intermediate (or adhesive) layer preferably has a similar or higher refractive index than that of the current spreading layer.

The invention provides a light emitting diode (LED) which includes a conductive n-type region; a p-type region formed on the active region; a current spreading layer formed on top of the p-type region; an optically transparent intermediate layer; and a crystalline epitaxial film light extraction layer at the surface; a plurality of nano/micro structures are formed on the crystalline epitaxial film light extraction layer for light extraction from the active region, and the nanostructures having a diameter of at least 100 nm and up to 10 μm.

The shape of the nano/micro structures may be at least one of a square, circle, triangle or combination thereof.

The nano/micro structures may have a height of between 10 nm and 10 μm.

The current spreading layer may be made of indium tin oxide.

The crystalline epitaxial film light extraction layer may be any one or more of GaN, AlGaN, InGaN, AlInGaN, or diamond.

The invention provides a method of making a light emitting diode (LED. The method includes forming a conductive n-type region on a substrate; forming an active region on the n-type region; forming a p-type region on the active region (thereby referred to as the host wafer); and preparing a crystalline epitaxial film light extraction layer on a separate substrate (thereby referred to as the sacrificial substrate); mechanically bonding the crystalline epitaxial film light extraction layer on the sacrificial substrate onto the p-type region on the host wafer; removing the sacrificial substrate; and forming nano/micro structures onto an exposed surface of the crystalline epitaxial film light extraction layer.

The crystalline epitaxial film light extraction layer on the sacrificial substrate is grown on a sapphire, silicon or silicon carbide substrate.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

The invention thereby provides an LED device with nano/micro structures formed on a crystalline epitaxially grown film on top of the current spreading layer on an LED device structure. By selecting a high refractive index crystalline film, high light extraction efficiency can be achieved with this structure. The invention further provides a method of producing the same.

1. A light emitting diode, comprising:
an active region in combination with a current spreading layer; and
a crystalline epitaxial film light extraction layer in contact with the current spreading layer, the light extraction layer being patterned with nano/micro structures which increase extraction of light emitted from the active region.

2. The light emitting diode according to claim 1, wherein the active region in combination with the current spreading layer comprises a conductive n-type region on a substrate, the active region on the n-type region, a p-type region on the active region, and the current spreading layer on the p-type region.

3. The light emitting diode according to claim 1, wherein the crystalline epitaxial film light extraction layer is bonded directly onto the current spreading layer.

4. The light emitting diode according to claim 1, wherein the crystalline epitaxial light extraction layer is bonded onto the current spreading layer with an intermediate adhesive layer.

5. The light emitting diode according to claim 4, wherein the intermediate adhesive layer is optically transparent and has a similar or higher refractive index than a refractive index of the current spreading layer.

6. The light emitting diode according to claim 1, wherein the crystalline epitaxial film light extraction layer has a doping level equal to or greater than 10¹⁸ cm⁻³.

7. The light emitting diode according to claim 1, wherein a shape of the nano/micro structures is at least one of a square, circle, triangle or combination thereof.

8. The light emitting diode according to claim 1, wherein the nano/micro structures have a height of between 10 nm and 10 μm, and a diameter of between 100 nm and 10 μm.

9. The light emitting diode according to claim 1, wherein the current spreading layer is made of indium tin oxide, indium zinc oxide, zinc oxide or indium zinc tin oxide.

10. The light emitting diode according to claim 1, wherein the crystalline epitaxial film light extraction layer is any one or more of GaN, AlGaN, InGaN, AlInGaN, or diamond.

11. A method of making a light emitting diode, comprising:
forming an active region in combination with a current spreading layer; and
providing a crystalline epitaxial film light extraction layer in contact with the current spreading layer, the light extraction layer being patterned to form nano/micro structures which increase extraction of light emitted from the active region.

12. The method according to claim 11, comprising:
forming the active region in combination with the current spreading layer on a first substrate;
expitaxially growing the crystalline epitaxial film light extraction layer on a second substrate that is separate from the first substrate; and
mechanically bonding the crystalline epitaxial film light extraction layer on the second substrate to the current spreading layer on the first substrate.

13. The method according to claim 11, comprising:
forming a conductive n-type region on a first substrate, forming the active region on the n-type region, forming a p-type region on the active region, and forming the current spreading layer on the p-type region;
epitaxially growing the crystalline epitaxial film light extraction layer on a second substrate that is separate from the first substrate;
mechanically bonding the crystalline film light extraction layer on the second substrate to the p-type region on the first substrate;
following the mechanical bonding, removing the second substrate; and
forming the nano/micro structures on a surface of the crystalline film light extraction layer exposed by the removal of the second substrate.

14. The method according to claim 12, wherein the crystalline epitaxial film light extraction layer is mechanically bonded directly onto the current spreading layer.

15. The method according to claim 12, wherein the crystalline epitaxial light extraction layer is mechanically bonded onto the current spreading layer using an intermediate adhesive layer.

16. The method according to claim 15, wherein the intermediate adhesive layer is optically transparent and has a similar or higher refractive index than a refractive index of the current spreading layer.

17. The method according to claim 12, wherein the second substrate is one of a sapphire, silicon or silicon carbide substrate.

18. The method according to claim 11, wherein a shape of the nano/micro structures is at least one of a square, circle, triangle or combination thereof.

19. The method according to claim 11, wherein the nano/micro structures have a height of between 10 nm and 10 μm.

20. The method according to claim 11, wherein the nano/micro structures have a diameter of between 100 nm and 10 μm.

21. The method according to claim 11, wherein the current spreading layer is made of indium tin oxide, indium zinc oxide, zinc oxide or indium zinc tin oxide.

22. The method according to claim 11, wherein the crystalline epitaxial film light extraction layer is any one or more of GaN, AlGaN, InGaN, AlInGaN, or diamond.

23. The method according to claim 11, wherein the crystalline epitaxial film light extraction layer has a doping level equal to or greater than 10¹⁸ cm⁻³.
